(19) United States
(12) Patent Application Publication
(10) Pub. No.: US 2011/0018013 A1
(43) Pub. Date: Jan. 27, 2011

(54) THIN-FILM FLIP-CHIP SERIES CONNECTED LEDS

(75) Inventors: Tal MARGALITH, Pleasanton, CA (US); Henry Kwong-Hin CHOY, Sunnyvale, CA (US); John E. EPLER, San Jose, CA (US); Stefano SCHIAFFINO, Pleasanton, CA (US)

Correspondence Address: PHILIPS INTELLECTUAL PROPERTY & STANDARDS, P.O. BOX 3001, BRIARCLIFF MANOR, NY, 10510, US

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/506,774

(22) Filed: Jul. 21, 2009

(51) Int. Cl. H01L 33/00

(52) U.S. Cl. 257/91; 438/28; 438/29; 257/99; 257/E33.066; 257/E33.057; 257/93

(57) ABSTRACT

A light-emitting diode (LED) is fabricated by forming the LED segments with bond pads covering greater than 85% of a mounting surface of the LED segments and isolation trenches that electrically isolate the LED segments, mounting the LED segments on a submount with a bond pad that couples two or more bond pads from the LED segments, and applying a laser lift-off to remove the growth substrate from the LED layer.

### FIELD OF INVENTION

The present disclosure relates to light-emitting diodes or devices (LEDs) and, in particular, to flip chip LEDs.

### DESCRIPTION OF RELATED ART

Semiconductor LEDs are among the most efficient light sources currently available. Materials systems currently of interest in the manufacture of high-brightness light emitting devices capable of operation across the visible spectrum include Group III-V semiconductors; for example, binary, ternary, and quaternary alloys of gallium, aluminum, indium, nitrogen, phosphorus, and arsenic. III-V devices emit light across the visible spectrum. GaAs- and GaP-based devices are often used to emit light at longer wavelengths such as yellow through red, while III-nitride devices are often used to emit light at shorter wavelengths such as near-UV through green.

Gallium nitride LEDs typically use a transparent sapphire growth substrate due to the crystal structure of sapphire being similar to the crystal structure of gallium nitride.

Some GaN LEDs are formed as flip chips, with both electrodes on the same surface, where the LED electrodes are bonded to electrodes on a submount without using wire bonds. In such a case, light is transmitted through the transparent sapphire substrate, and the LED layers oppose the submount. A submount provides an interface between the LED and an external power supply. Electrodes on the submount bonded to the LED electrodes may extend beyond the LED or extend to the opposite side of the submount for wire bonding or surface mounting to a circuit board.

### SUMMARY

In some embodiments of the present disclosure, a light-emitting diode or device (LED) is fabricated by forming LED segments with bond pads covering greater than 85% of a mounting surface of the LED segments and isolation trenches that electrically isolate the LED segments, mounting the LED segments on a submount with a bond pad that couples two or more bond pads of the LED segments, and applying a laser lift-off to remove the growth substrate from the LED layer.

### BRIEF DESCRIPTION OF THE DRAWINGS

In the drawings:

FIG. 1 illustrates a cross-sectional view of a first example light-emitting diode or device (LED);

FIG. 2 is a flowchart of an example method for fabricating the LED of FIG. 1;

FIGS. 3, 4, and 5 illustrate cross-sectional views of fabrication of the LED of FIG. 1;

FIG. 6 is a cross-sectional view of a second example light-emitting diode (LED);

FIG. 7 is a flowchart of an example method for fabricating the LED of FIG. 6; and

FIGS. 8, 9, and 10 illustrate cross-sectional views of fabrication of the LED of FIG. 6, all arranged in accordance with one or more embodiments of the invention.

Use of the same reference numbers in different figures indicates similar or identical elements.

### DETAILED DESCRIPTION

Light-emitting diode or device (LED) configurations that allow direct drive from AC mains (120V or 230V) are attractive for applications requiring a small footprint for the light-source, which are driven by cost, efficiency, or design flexibility requirements. In some configurations, LED junctions are connected, on-chip or on-submount, in series as a single string with a rectifier circuit or as a pair of anti-parallel strings in series with a ballast resistor. A similar configuration (series-connected junctions) can be used for any application where the forward operating voltage is greater than the forward voltage of one diode (e.g., a 12V or 24V configuration operated by a driver circuit).

Prior to creating the series or parallel connections, each individual LED segment in a string is electrically isolated from its neighbors in order to avoid short-circuiting through the conductive n-type epitaxial layers. One method of isolation involves a “trench” etch—removing the epitaxial material between the LED segments down to a non-conductive substrate. However, this trenching approach may be incompatible with the underfill process in the fabrication of a Thin Film Flip Chip (TTFC), which uses an underfill material to provide mechanical support and seal the voids between the thin LED layers and the submount. An interface between the growth wafer and the underfill material would be formed in the isolation trench prior to laser lift-off of the growth wafer. At that interface, the underfill material would be exposed to the full power of the laser during the lift-off process and may thermally expand and damage the LED layers. Furthermore, the underfill material may stick to and hamper the release of the sapphire substrate.

Very Large Area (VLA) interconnects (e.g., bond pads) with greater than 85% surface coverage have been shown to decrease the thermal resistance of the LED die on submount construct, and to enable underfill-free support of the LED layers during TFFC processing. The former enables LED to be driven at higher currents or temperatures, while the latter serves as both a cost-reduction and a potentially more stable process that is independent of yield/reliability fluctuations resulting from the underfill epoxy material selection, dispense, cure, and removal.

In one or more embodiments of the present disclosure, LED segments are metalized with VLA bond pads and trench isolated. The VLA bond pads support the entire LED string during laser lift-off of the growth substrate, thereby avoiding any growth wafer/underfill interface issues with the isolation trenches. The series or parallel connections of the LED segments may occur through metallization on the LED die or on a submount.

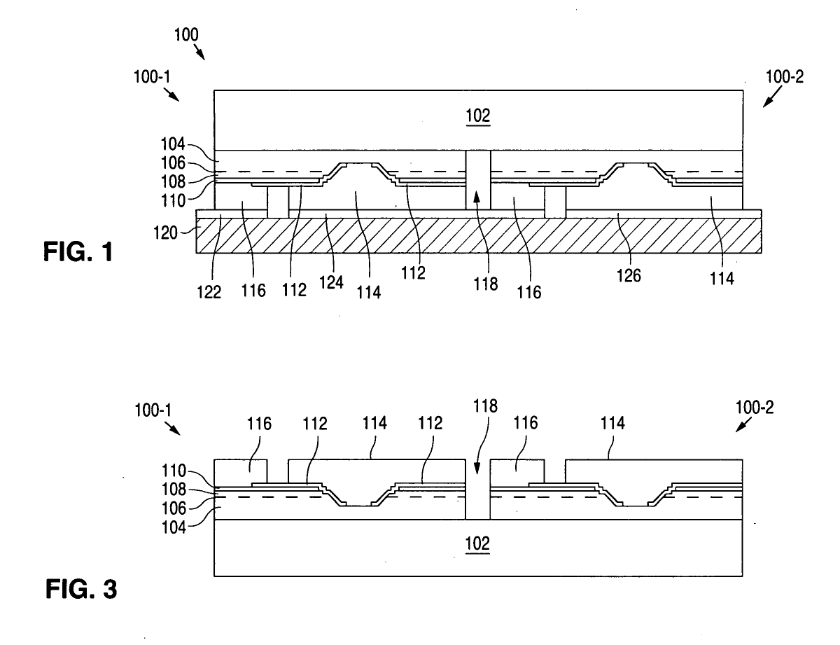

FIG. 1 illustrates a cross-sectional view of an example LED 100 in one or more embodiments of the present disclosure. Although a growth wafer 102 is shown, it is ultimately removed from the finished LED 100. LED 100 includes a string of LED segments 100-1 and 100-2 connected in series. An LED segment may be an individual LED die that it is electrically coupled with one or more other LED segments and packaged as a single LED. LED 100 may include additional LED segments. LED 100 may have LED segments 100-1 and 100-2 connected in parallel instead of in series.

LED segments 100-1 and 100-2 have substantially the same structure so only the structure of LED segment 100-1 is described. LED segment 100-1 includes LED layers formed over a growth wafer 102 such as sapphire. The LED layers include an n-type layer 104, a light-emitting layer 106 (also commonly referred to as the active region) over the n-type layer, and a p-type layer 108 over the light-emitting layer. A conductive reflective layer 110 is formed over p-type layer 108. One or more vias are formed through conductive reflective layer 110, p-type layer 108, and light-emitting layer 106 to provide access to n-type layer 104.

A dielectric layer 112 is formed over conductive reflective layer 110 and the vias. Openings are formed in dielectric layer 112 to expose n-type layer 104 and conductive reflective layer 110 to p-type layer 106. One or more n-type bond pads 114 are formed over the exposed n-type layer 104, and one or more p-type bond pads 116 are formed over the exposed conductive reflective layer 110 to p-type layer 106. Bond pads 114 and 116 on the back surface of the LED die (LED segments 100-1 and 100-2) extend to the die edge and cover greater than 85% of the back surface so the bond pads support almost the entire back surface.

LED segments 100-1 and 100-2 are electrically isolated from each other to avoid short-circuiting through n-type layer 104. LED segments 100-1 and 100-2 may be electrically isolated by one or more isolation trenches 118 etched down to growth wafer 102. Alternatively, LED segments 100-1 and 100-2 may be electrically isolated by one or more electrically insulating regions (at the location of isolation trenches 118) formed by ion implantation.

LED segments 100-1 and 100-2 are mounted on a submount 120. Submount 120 may include through-via or on-submount redistribution of the metal pattern. Submount 120 includes bond pads 122, 124, and 126. Bond pad 122 receives p-type bond pad 116 of LED segment 100-1, and bond pad 126 receives n-type bond pad 114 of LED segment 100-2. Bond pad 124 receives n-type bond pad 114 of LED segment 100-1 and p-type bond pad 116 of LED segment 100-2, thereby connecting the LED segments in series. After LED segments 100-1 and 100-2 are mounted on submount 120, a laser lift-off process is used to remove growth wafer 102. As underfill is not used, no damage from the growth wafer/underfill interface can occur in the laser lift-off process.

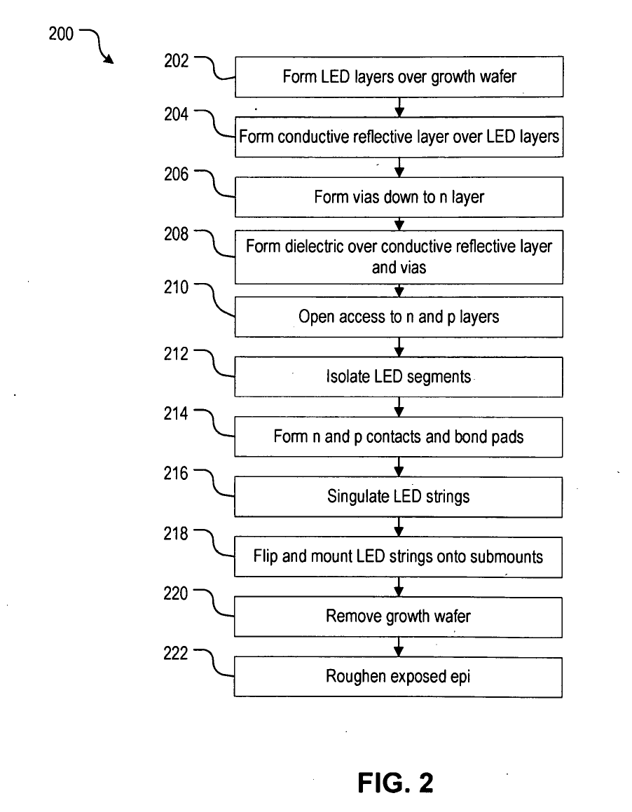

FIG. 2 is a flowchart of an example method 200 for forming LED 100 in one or more embodiments of the present disclosure. Method 200 includes processes 202, 204, 206, 208, 210, 212, 214, 216, 218, 220, and 222.

In process 202, LED layers 104, 106, and 108 are formed over growth wafer 102. N-type layer 104 is epitaxially grown over growth wafer 102. N-type layer 104 represents multiple layers of different compositions and dopant concentration including, for example, preparation layers such as buffer layers or nucleation layers which may be n-type or not intentionally doped, release layers designed to facilitate later release of the growth wafer or thinning of the semiconductor structure after substrate removal, and n-type device layers designed for particular optical or electrical properties desirable for a light-emitting layer to efficiently emit light. The n-type device layers in a III-nitride light emitting device may be GaN.

Light-emitting layer 106 is epitaxially grown over n-type layer 104. Light-emitting layer 106 may be represented by multiple thin quantum well light-emitting layers separated by barrier layers. In a III-nitride light emitting device configured to emit visible light, in particular near-UV through green light, the light-emitting layer may be InGaN.

P-type layer 108 is epitaxially grown over light-emitting layer 106. P-type layer 108 represents multiple layers of different composition, thickness, and dopant concentration, including p-type device layers. The p-type device layers in a III-nitride light emitting device may be GaN.

In process 204, conductive reflective layer 110 is formed over the LED layers. Conductive reflective layer 110 represents multiple layers including an ohmic contact layer, a reflective layer, and a guard metal layer. The ohmic contact layer may be Ni, Ag, or Pd, the reflective layer may be Ag, and the guard metal layer may be multiple layers including TiW/TiW:N/TiW. Conductive reflective layer 110 may be patterned by a lift-off process.

In process 206, vias are formed through conductive reflective layer 110, p-type layer 108, and light-emitting layer 106 to provide access to n-type layer 104. The vias may be formed by etching.

In process 208, dielectric layer 112 is deposited over conductive reflective layer 110 and the vias to electrically isolate the vias. Dielectric layer 112 may be SiNx.

In process 210, openings are patterned in dielectric layer 112 to provide access to n-type layer 104 at the bottom of the vias. Openings are also patterned in dielectric layer 112 to provide access to conductive reflective layer 114 for p-type layer 108. Dielectric layer 112 may be patterned by etching.

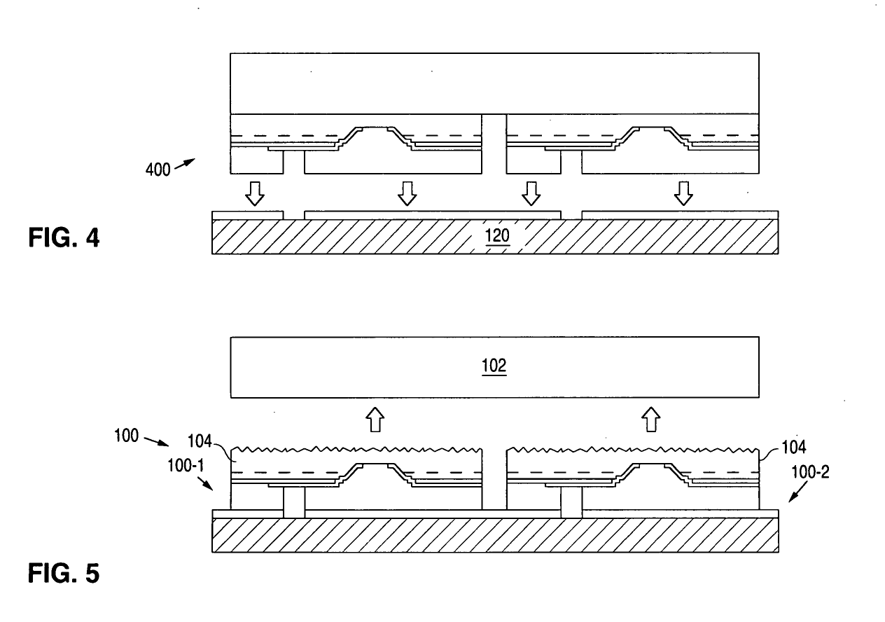

In process 212, LED segments (e.g., LED segments 100-1 and 100-2) are electrically isolated. LED segments 100-1 and 100-2 may be electrically isolated by etching isolation trenches 118 down to growth wafer 102. The resulting structure is shown in FIG. 3. Alternatively, LED segments 100-1 and 100-2 may be electrically isolated by one or more electrically insulating regions (at the location of isolation trenches 118) formed by ion implantation. At this point, individual LED segments are defined.

For more information related to processes 212, please refer to U.S. patent application Ser. No. 12/266,162, entitled “Series Connected Flip Chip LEDs with Growth Substrate Removed,” filed on Nov. 6, 2008, attorney docket no. LUM-06-11-11, which is commonly assigned and incorporated by reference.

In process 214, n-type and p-type contacts (not illustrated) and bond pads are formed. A contact metal is deposited over the exposed n-type layer 104 and the exposed conductive reflective layer 114 for p-type layer 108. The contact metal is patterned to electrically insulate the n-type and the p-type contacts. The contact metal may be Ti, Al, or Ti/Au. The contact metal may be formed by a lift-off process.

A bond metal is deposited over the contact metal to form n-type bond pads 114 and p-type bond pads 116. The bond metal may be Au, Cu, Al, Ni, or a combination of those layers. The bond metal may be formed electro-chemically (e.g., electro-plating) or by other physical deposition method (e.g., evaporation or sputtering). As described above, bond pads 114 and 116 cover greater than 85% of the back surface of the LED die (LED segments 100-1 and 100-2).

For more information related to process 212, please refer to U.S. patent application Ser. No. 11/611,775, entitled “LED Assembly Having Maximum Metal Support for Laser Lift-off of Growth Substrate,” filed on Dec. 15, 2006, attorney docket no. LUM-06-03-01, which is commonly assigned and incorporated by reference.

In process 216, LED strings or groups of LED strings are singulated from the device wafer. The LED strings may be singulated by a laser, a scribe, or a saw along the singulation streets between the LED strings.

In process 218, the LED strings or groups of LED strings are flipped over, aligned, and bonded to submounts. As shown in FIG. 4, an LED string 400 including LED segments 100-1 and 100-2 is bonded to submount 102. The LED strings may be bonded to the LED submounts by ultrasonic or thermosonic bonding.

In process 220, growth substrate 102 is removed as shown in FIG. 5. Growth substrate 102 may be removed by a laser lift-off process. In the laser lift-off process, a laser ablates the material at the interface of growth substrate 102 and n-type layer 104.

In process 222, the top surface of n-type layer 104 is roughened to improve light extraction as shown in FIG. 5 to complete LED 100. N-type layer 104 may be roughened in a physical process (e.g., grinding or lapping) or a chemical process (e.g., etching).

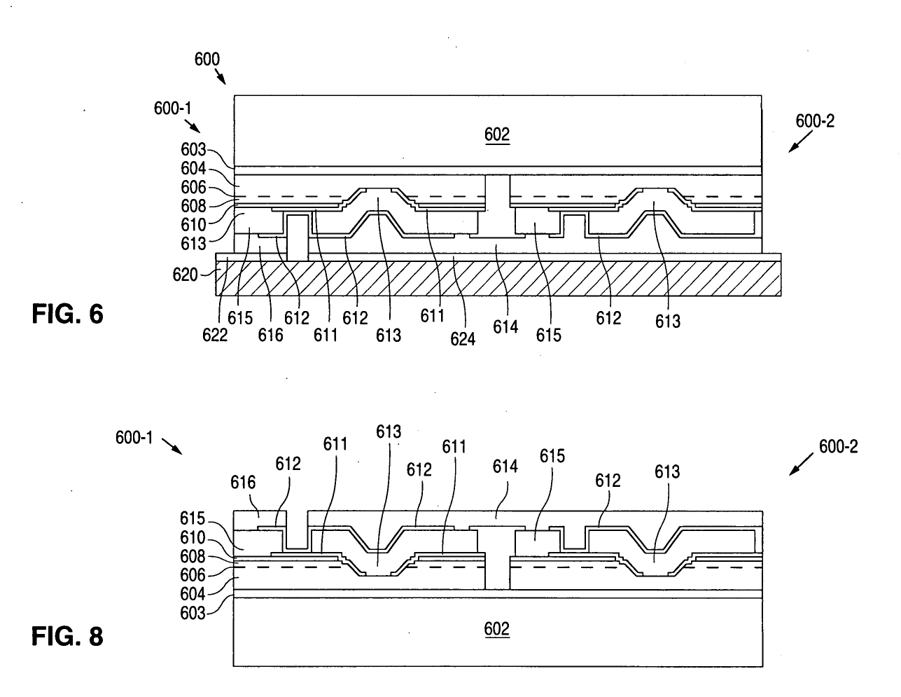

FIG. 6 shows a cross-sectional view of an example LED 600 in one or more embodiments of the present disclosure. Although a growth wafer 602 is shown, it is ultimately removed from the finished LED 600. LED 600 includes a string of LED segments 600-1 and 600-2 connected in series. LED 600 may include additional LED segments. LED 600 may have LED segments 600-1 and 600-2 connected in parallel instead of in series.

LED segments 600-1 and 600-2 have substantially the same structure so only the structure of LED segment 600-1 is described in full. LED segment 600-1 may include an optional semi-insulating layer 603, which is formed over a growth substrate 602 such as sapphire. LED layers are formed over semi-insulating layer 603 or growth wafer 602. The LED layers may include an n-type layer 604, a light-emitting layer 606 over the n-type layer, and a p-type layer 608 over the light-emitting layer. A conductive reflective layer 610 is formed over p-type layer 608. One or more vias are formed through conductive reflective layer 610, p-type layer 608, and light-emitting layer 606 to provide access to n-type layer 604.

A first dielectric layer 611 is formed over conductive reflective layer 610 and the vias. Openings are formed in first dielectric layer 611 to expose n-type layer 604 and conductive reflective layer 610 to p-type layer 606. One or more n-type contacts 613 are formed over the exposed n-type layer 604, and one or more p-type contacts 615 are formed over the exposed conductive reflective layer 610 to p-type layer 608.

LED segments 600-1 and 600-2 are electrically isolated from each other to avoid short-circuiting through n-type layer 604. LED segments 600-1 and 600-2 may be electrically isolated by one or more isolation trenches etched down to semi-insulating layer 603 or growth wafer 602. Alternatively, LED segments 600-1 and 600-2 may be electrically isolated by one or more electrically insulating regions formed by ion implantation.

A second dielectric layer 612 is formed over contacts 613 and 615 of LED segments 600-1 and 600-2. Second dielectric layer 612 enables the series or the parallel connections between LED segments 600-1 and 600-2 to be made on the LED die instead of on a submount, which in turn allows for a simpler design of the metallization on the submount. Second dielectric layer 612 may also fill in the isolation trenches between LED segments 600-1 and 600-2.

Openings are formed in second dielectric layer 612 to selectively expose contacts 613 and 615 of LED segments 600-1 and 600-2, and bond pads are formed over the exposed contacts 613 and 615 to connect individual LED segments, in series or in parallel, per the circuit design. For example, FIG. 6 shows that one or more bond pads 614 are formed over the exposed n-type contacts 613 of LED segment 600-1 and the exposed p-type contacts 615 of LED segment 600-2, and one or more bond pads 616 are formed over the exposed p-type interconnects 615 of LED segment 600-1. Bond pads 614 and 616 on the back surface of the LED die (LED segments 600-1 and 600-2) extend to the die edge and cover greater than 85% of the back surface so the bond pads support almost the entire back surface.

LED segments 600-1 and 600-2 are mounted on a submount 620. As redistribution of the metal pattern is already provided by LED segments 600-1 and 600-2, submount 620 may be of a simple design with a matching metal pattern. Submount 620 includes bond pads 622 and 624 for receiving bond pads 614 and 616 LED segments 600-1 and 600-2. After LED segments 600-1 and 600-2 are mounted on submount 620, a laser lift-off process is used to remove growth substrate 602. As underfill is not used, no damage from the growth wafer/underfill interface can occur in the laser lift-off process.

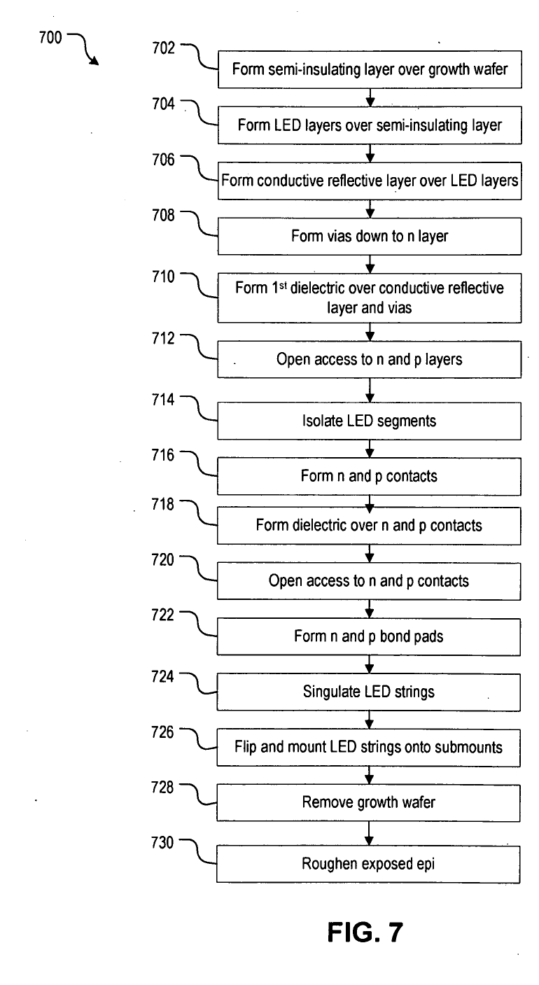

FIG. 7 is a flowchart of an example method 700 for forming LED 600 in one or more embodiments of the present disclosure. Method 700 includes processes 702, 704, 706, 708, 710, 712, 714, 716, 718, 720, 722, 724, 726, 728, and 730.

In process 702, optional semi-insulating layer 603 may be formed over growth wafer 602. Semi-insulating layer 603 may be epitaxially grown over growth wafer 602. Semi-insulating layer 603 in a III-nitride light emitting device may be GaN, and it may be p-type, n-type, codoped, or undoped. Semi-insulating layer 603 may be formed by ion implantation with an approximate dose and energy of 8E13 cm⁻² and 400 keV, respectively, for a 4 micron thick epitaxial layer. Implantation species may be He, Zn, Al, or Mg.

Semi-insulating layer 603 may be doped with deep level impurities such as Fe, C, Co, Mn, Cr, V, Ni, and/or other transition metal dopants by ion implantation or during epitaxial growth. A deep level dopant may be used in combination with a shallow level dopant such as Si, Ge, O, Mg, or Zn at a concentration less than about 1×10¹⁷ cm⁻³. The deep level impurity may have a concentration greater than about 1×10¹⁷ cm⁻³.

In process 704, LED layers 604, 606, and 608 are formed over semi-insulating layer 603 or growth wafer 602 as similarly described above for process 202.

In process 706, conductive reflective layer 610 is formed over the LED layers as similarly described above for process 204.

In process 708, vias are formed to provide access to n-type layer 604 as similarly described above for process 206.

In process 710, first dielectric layer 611 is deposited over conductive reflective layer 610 and the vias as similarly described above for process 208.

In process 712, openings are patterned in first dielectric layer 611 to provide access to n-type layer 604 and conductive reflective layer 614 for p-type layer 608 as similarly described above for process 210.

In process 714, LED segments (e.g., LED segments 600-1 and 600-2) are electrically isolated. LED segments 600-1 and 600-2 may be electrically isolated by etching isolation trenches down to optional semi-insulating layer 603 or growth wafer 602. Alternatively, LED segments 600-1 and 600-2 may be electrically isolated by one or more electrically insulating regions (at the location of isolation trenches) formed by ion implantation. At this point, individual LED segments are defined.

For more information related to processes 716, please refer to U.S. patent application Ser. No. 12/266,162, entitled “Series Connected Flip Chip LEDs with Growth Substrate Removed,” filed on Nov. 6, 2008, attorney docket no. LUM-06-11-11, which is commonly assigned and incorporated by reference.

In process 716, n-type contacts 613 and p-type contacts 615 are formed. A contact metal is deposited over the exposed n-type layer 604 and the exposed conductive reflective layer 614 for p-type layer 608. The contact metal is patterned to electrically isolate the n-type and the p-type contacts. The contact metal may be Ti, Al, or Ti/Au. The contact metal may be formed by a lift-off process.

In process 718, second dielectric layer 612 is deposited over contacts 613 and 615. Second dielectric layer 612 may be SiNx.

In process 720, openings are patterned in second dielectric layer 612 to provide access to contacts 613 and 615 per the circuit design.

Processes 716 to 720 may be repeated to add additional layers of redistribution. For more information related to processes 716 to 720, please refer to U.S. Pat. No. 6,828,596, which is commonly assigned and incorporated herein by reference.

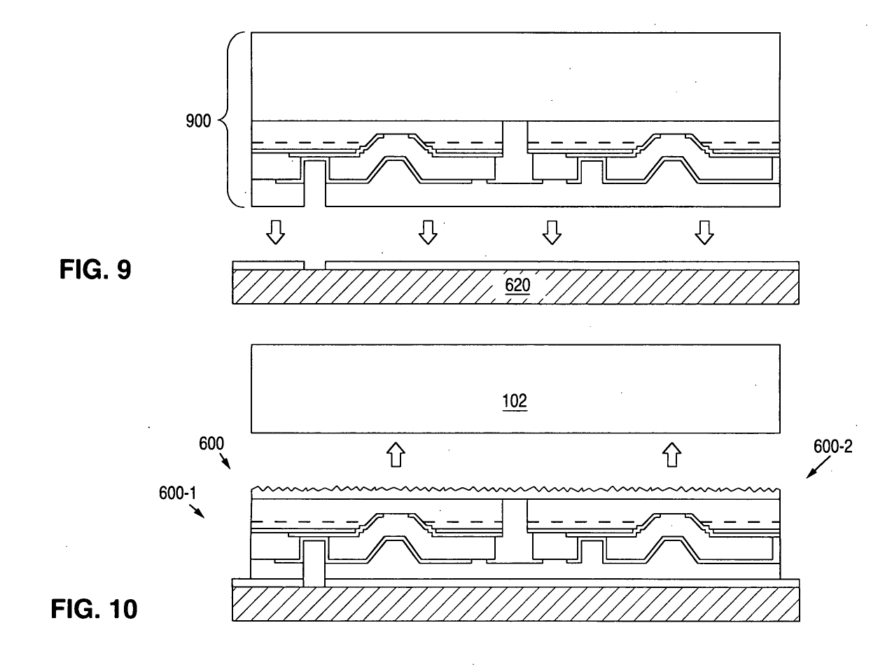

In process 722, bond pads are formed. A bond metal is deposited over the exposed contacts 613 and 615 and patterned per the circuit design to form bond pads 614 and 616. The bond metal may be Au, Cu, Al, Ni, or a combination of those layers. The bond metal may be formed electro-chemically (e.g., electro-plating) or by other physical deposition method (e.g., evaporation or sputtering). As described above, bond pads 614 and 616 cover greater than 85% of the back surface of the LED die (LED segments 600-1 and 600-2). The resulting structure is shown in FIG. 8.

For more information related to process 722, please refer to U.S. patent application Ser. No. 11/611,775, entitled “LED Assembly Having Maximum Metal Support for Laser Lift-off of Growth Substrate,” filed on Dec. 15, 2006, attorney docket no. LUM-06-03-01, which is commonly assigned and incorporated by reference.

In process 724, LED strings or groups of LED strings are singulated from the device wafer as similarly described above for process 216.

In process 726, the LED strings or groups of LED strings are flipped over, aligned, and bonded to submounts as similarly described above for process 218. As shown in FIG. 9, an LED string 900 including LED segments 600-1 and 600-2 is bonded to submount 602.

In process 728, growth substrate 602 is removed as shown in FIG. 10. Step 728 is similarly to step 220 described above.

In process 730, the top surface of n-type layer 604 is roughened to improve light extraction as shown in FIG. 10 to complete LED 600. Step 730 is similarly to step 222 described above.

Various other adaptations and combinations of features of the embodiments disclosed are within the scope of the invention. Although a GaN based LED with a sapphire growth wafer is described, other types of LEDs using other substrates such as SiC (used to form an InAlGaN LED) and GaAs (used to form an AlInGaP LED) may benefit from the present disclosure. Although the n-type, the light-emitting, and the p-type layers are arranged in a specific orientation, the order may be reversed in other embodiments. Although a specific sequence of processes is provided for fabricating an LED, the sequence may be changed to achieve the same structure. For example, processes 212 may be performed after process 214, and process 712 may be performed after process 714. Numerous embodiments are encompassed by the following claims.

What is claimed is:

1. A method for forming a light-emitting device (LED) comprising two or more LED segments, comprising:
forming the LED segments, comprising:
forming LED layers over a growth substrate, the LED layers comprising a first conductivity type layer, a light-emitting layer over the first conductivity layer, and a second conductivity type layer over the light-emitting layer;
electrically isolating the LED layers to form the LED segments; and
forming bond pads coupled to the first conductivity type layer and the second conductivity type layer, the bond pads covering greater than 85% of a mounting surface of the LED segments;
mounting the LED segments on a submount, the submount comprising a bond pad that couples two or more bond pads from two or more LED segments; and
removing the growth substrate from the LED layers.

2. The method of claim 1, wherein electrically isolating the LED layers comprises forming isolation trenches through the LED layers.

3. The method of claim 1, wherein removing the growth substrate from the LED layers comprises applying a laser lift-off to remove the growth substrate from the LED layers.

4. The method of claim 1, wherein the bond pad of the submount couples the LED segments in series or in parallel.

5. The method of claim 1, wherein forming the LED segments further comprises forming a semi-insulating layer over the growth substrate, wherein the LED layers are formed over the semi-insulating layer.

6. The method of claim 5, wherein electrically isolating the LED layers comprises forming isolation trenches through the LED layers down to the semi-insulating layer.

7. The method of claim 1, wherein forming the LED segments further comprises:
forming a first dielectric layer over the LED layers;
forming contacts over the first dielectric layer, the contacts being electrically coupled to the first conductivity type layer and the second conductivity type layer; and
forming a second dielectric layer over the contacts, wherein the bond pads are electrically coupled by the contacts to the first conductivity type and the second conductivity type layers.

8. A light-emitting device (LED), comprising:
two or more electrically isolated LED segments, comprising:
LED layers comprising a first conductivity type layer, a light-emitting layer over the first conductivity layer, and a second conductivity type layer over the light-emitting layer; and
bond pads coupled to the first conductivity type layer and the second conductivity type layer, the bond pads covering greater than 85% of a mounting surface of the LED segments; and
a submount comprising a bond pad that couples two or more bond pads from two or more LED segments.

9. The LED of claim 8, wherein the LED segments are electrically isolated by isolation trenches through the LED layers.

10. The LED of claim 8, wherein the bond pad of the submount couples the LED segments in series or in parallel.

11. The LED of claim 8, wherein the LED segments further comprise a semi-insulating layer, wherein the LED layers are formed over the semi-insulating layer.

12. The LED of claim 11, wherein the LED segments are electrically isolated by isolation trenches through the LED layers down to the semi-insulating layer.

13. The LED of claim 8, wherein the LED segments further comprise:
a first dielectric layer over the LED layers;
contacts over the first dielectric layer, the contacts being electrically coupled to the first conductivity type layer and the second conductivity type layer; and
a second dielectric layer over the contacts, wherein the bond pads are electrically coupled by the contacts to the first conductivity type and the second conductivity type layers.
